(19) United States
(12) Patent Application Publication
(10) Pub. No.: US 2010/0089449 A1
(43) Pub. Date: Apr. 15, 2010

(54) HIGH EFFICIENCY SOLAR CELL AND MANUFACTURING METHOD THEREOF

(75) Inventors: Seh-Won Ahn, Seoul (KR); Kun-Ho Ahn, Seoul (KR); Kwy-Ro Lee, Seoul (KR); Don-Hee Lee, Seoul (KR); Heon-Min Lee, Seoul (KR)

Correspondence Address: MCKENNA LONG & ALDRIDGE LLP, 1900 K STREET, NW, WASHINGTON, DC, 20006, US

(73) Assignee: LG ELECTRONICS INC., Seoul (KR)

(21) Appl. No.: 12/308,713

(22) PCT Filed: Jul. 3, 2007
(86) PCT No.: PCT/KR2007/003208

§ 371 Date: Dec. 2, 2009

(30) Foreign Application Priority Data
Jul. 3, 2006 (KR) 10-2006-0062079

(51) Int. Cl. H01L 31/00; H01L 31/042; H01L 31/18; H01L 31/20

(52) U.S. Cl. 136/258; 438/96; 438/73; 257/E31.047; 257/E31.032

(57) ABSTRACT

The present invention relates to a high efficiency solar cell and a manufacturing method thereof. The high efficiency solar cell of the present invention comprises a lower solar cell layer comprising a single crystalline silicon-based pn thin film; an upper solar cell layer stacked on the upper portion of the lower solar cell layer and comprising an amorphous silicon-based pin thin film; and a glass substrate formed on the upper portion of the upper solar cell layer to receive sunlight. According to the present invention, it has an effect that a low-cost high efficiency solar cell can be manufactured.

### TECHNICAL FIELD

The present invention relates to a high efficiency solar cell and manufacturing method thereof.

### BACKGROUND ART

The currently commercialized method, which has been proposed to manufacture a low-cost solar cell, uses a silicon thin film technique to manufacture a transparent electrode, amorphous silicon p-layer, i-layer, and n-layer, and a transparent electrode on a glass substrate. The following methods have been attempted to raise the efficiency of such a thin film solar cell.

The process technique of the low-cost thin film solar cell comprises the steps of: depositing a transparent electrode on a glass substrate; texturing the transparent electrode using a weak acidic aqueous solution; manufacturing a p-type silicon thin film; adjusting an interface between p-type and i-type semiconductors; manufacturing an i-type semiconductor thin film; manufacturing an n-type semiconductor thin film; manufacturing a backside reflection thin film; and manufacturing a backside electrode, etc. Also, a need exists for an optical and electrical simulation technique for the structure of the low-cost thin film solar cell. The conventionally commercialized technique, which has been proposed to manufacture the high efficiency solar cell, raises the efficiency of the solar cell up to 20% by stacking an intrinsic silicon thin film on the upper and lower portions of a single crystalline or a polycrystalline substrate, which is a heterojunction with intrinsic layer (HIT) silicon wafer available from Sanyo Co. of Japan.

The process technique of the solar cell using the existing silicon wafer comprises the steps of: preparing a substrate by growing and cutting an n-type or a p-type silicon wafer; forming a p-type or an n-type junction; forming a metal electrode; depositing an anti-reflective coating and a surface passivation film; doping a backside; and forming an electrode, etc. The HIT solar cell needs the process technique as well as the conditions for forming the p-type, i-type, and n-type thin films.

The operation of the thin film solar cell follows the principle as follows. The incident sunlight is absorbed into the intrinsic silicon thin film layer. At this time, electron-hole is generated. In the p-i-n structure, the electron and hole are moved into the n-type and p-type semiconductors, respectively, by means of built-in potential generated by the p-type and the n-type layers. FIG. 1 shows a structure of a double junction solar cell proposed to raise the efficiency of the low-cost thin film solar cell. The double junction solar cell is referred to as a tandem type. The existing single junction solar cell generates photo electron-holes by using only a light absorbing band of a material used in the intrinsic semiconductor, while in the case of the double junction solar cell, since light not absorbed into the intrinsic semiconductor positioned on the upper portion thereof is absorbed into the intrinsic semiconductor positioned on the lower portion thereof, it can generate more photo electron-holes.

FIG. 2 shows light absorption coefficient according to wavelength per material. In the case of using amorphous silicon the light absorption becomes poor in an area of 1 to 1.5 eV, while in the case of using microcrystalline silicon the light absorption becomes high in this area. Accordingly, it can be expected that the efficiency of the double junction solar cell using the microcrystalline silicon together with the single amorphous silicon is considerably improved, as compared to the efficiency of the solar cell using only the single amorphous silicon.

The structure of the high efficiency HIT solar cell is the same as FIG. 3A and the operation thereof follows the principle as follows. The incident sunlight is absorbed into an n-type solar cell manufactured in a wafer to move holes into the p-type silicon thin film positioned on the upper portion thereof and electrons into the n-type semiconductor positioned on the lower portion thereof. Thereafter, these electrons and holes are collected and transferred into a metal electrode via transparent electrodes (TCO) positioned on the upper and lower portions thereof. The intrinsic semiconductor is positioned in a thin film form between the upper p-type and the lower n-type so that the existing passivation process is removed and the interface is formed between the p-type and n-type thin films at a low temperature so that the electron-hole recombination is reduced, making it possible to considerably improve the efficiency.

A manufacturing cost of the thin film solar cell can be relatively lowered, while it has a disadvantage that the efficiency is still low. The light conversion efficiency of the commercialized thin film solar cell module is slightly above about 10% even in the case of the tandem type. This value is inferior to the lowest efficiency of the solar cell using the Si wafer (the light conversion efficiency of the solar cell using the polycrystalline wafer is about 12 to 14% and the light conversion efficiency of the solar cell using the single crystalline wafer is about 14 to 18%). This is because the quality of the thin film in the solar cell using the thin film is poorer than compared to a bulk type solar cell.

The HIT solar cell, which is one of the high efficiency solar cells, is very expensive because it uses a more expensive silicon wafer than glass used as the substrate in the thin film solar cell and needs special equipment for depositing the thin film. Furthermore, since the HIT solar cell is more expensive than other types of solar cells even when considering module price per produced power, it is likely to be installed at a place with a limited area.

### DISCLOSURE

### Technical Problem

The present invention proposes to solve the above problems. It is an object of the present invention to provide a solar cell and a manufacturing method thereof using an advantage of a thin film solar cell and a layer transfer process (LTP) method, which has been developed through a silicon-on-insulator (SOI) method and which there have been attempts to apply to a solar cell in order to solve the problems that the efficiency of a low-cost thin film solar cell is low and that a high efficiency HIT solar cell is expensive.

### Technical Solution

In order to accomplish the above objects, a high efficiency solar cell according to an embodiment of the present invention, comprising: a lower solar cell layer comprising a single crystalline silicon-based pn thin film; an upper solar cell layer stacked on the upper portion of the lower solar cell layer and comprising an amorphous silicon-based pin thin film; and a glass substrate formed on the upper portion of the upper solar cell layer to receive sunlight. A high efficiency solar cell according another embodiment of the present invention, comprising: a silicon-based pn epitaxial thin film grown by a layer transfer process (LTP) method; a first amorphous silicon-based thin film formed on the lower portion of the silicon-based pn epitaxial thin film; a second amorphous silicon-based thin film formed on the upper portion of the silicon-based pn epitaxial thin film; an upper electrode and an upper metal emitter electrode formed on the upper portion of the first amorphous silicon-based thin film; a lower electrode and a lower metal emitter electrode formed on the lower portion of the second amorphous silicon-based thin film; and a glass substrate formed on the upper portion of the upper metal emitter electrode to receive sunlight.

A manufacturing method of a high efficiency solar cell according to an embodiment of the present invention, comprising the steps of: growing a silicon-based pn epitaxial thin film by a layer transfer process (LTP) method and sequentially forming an intermediate layer, an amorphous silicon-based pin thin film and an upper electrode on the silicon-based pn epitaxial thin film; and bonding a glass substrate to the upper portion of the upper electrode and sequentially forming a backside reflection thin film and a backside electrode on the lower portion of the silicon-based pn epitaxial thin film.

A manufacturing method of a high efficiency solar cell according to another embodiment of the present invention, comprising the steps of: growing a silicon-based pn epitaxial thin film by a layer transfer process (LTP) method; sequentially forming an upper electrode and an amorphous silicon-based pin thin film on a glass substrate; and bonding the silicon-based pn epitaxial thin film and the amorphous silicon-based pin thin film using an intermediate layer as a medium and sequentially forming a backside reflection thin film and a backside electrode on the lower portion of the silicon-based pn epitaxial thin film.

A manufacturing method of a high efficiency solar cell according to another embodiment of the present invention, comprising the steps of: growing a silicon-based pn epitaxial thin film by a layer transfer process (LTP) method and sequentially forming a metal emitter electrode, an insulating layer, a second electrode, an amorphous silicon-based thin film, and a first electrode on the upper portion of the silicon-based pn epitaxial thin film; sequentially forming an intermediate layer, an amorphous silicon-based pin thin film, and an upper electrode; and bonding a glass substrate to the upper portion of the upper electrode and sequentially forming a backside reflection thin film and a backside electrode on the lower portion of the silicon-based pn epitaxial thin film.

A manufacturing method of a high efficiency solar cell according to another embodiment of the present invention, comprising the steps of: growing a silicon-based pn epitaxial thin film by a layer transfer process (LTP) method and then forming a metal emitter electrode on the upper portion of the silicon-based pn epitaxial thin film; sequentially forming a first electrode, an amorphous silicon-based pin thin film and a second electrode on a glass substrate; and bonding the second electrode and the metal emitter electrode and sequentially forming a backside reflection thin film and a backside electrode on the lower portion of the silicon-based pn epitaxial thin film.

A manufacturing method of a high efficiency solar cell according to another embodiment of the present invention, comprising the steps of: growing a silicon-based n-type epitaxial thin film by a layer transfer process (LTP) method and sequentially stacking an i-type amorphous silicon-based thin film, a p-type amorphous silicon-based thin film, an upper electrode and an upper metal emitter electrode on the upper portion of the silicon-based n-type epitaxial thin film; and bonding a glass substrate to the upper portion of the upper metal emitter and sequentially stacking an i-type amorphous silicon-based thin film, a p-type amorphous silicon-based thin film, a lower electrode and a lower metal emitter electrode on the lower portion of the silicon-based pn epitaxial thin film.

A manufacturing method of a high efficiency solar cell according to another embodiment of the present invention, comprising the steps of: forming a metal emitter electrode on a single crystalline silicon-based pn thin film to form a lower solar cell layer; sequentially forming an upper transparent electrode, an amorphous silicon-based pin thin film and a lower transparent electrode on the upper portion of a glass substrate to form an upper solar cell layer; and bonding the lower solar cell layer and the upper solar cell layer.

### ADVANTAGEOUS EFFECTS

According to the present invention as described above, it has an effect that a low-cost high efficiency solar cell can be manufactured.

### DESCRIPTION OF DRAWINGS

The above and other objects, features and advantages of the present invention will be more clearly understood from the following detailed description taken in conjunction with the accompanying drawings, in which:

FIG. 1 shows a structure of a double junction solar cell proposed in order to raise the efficiency of a low-cost thin film solar cell;

FIG. 2 shows light absorption coefficient according to wavelength per material;

FIG. 3A shows a structure of a high efficiency HIT solar cell;

FIG. 3B is a process view showing a layer transfer process (LTP) using porous silicon;

FIGS. 4A and 4B are cross-sectional views of a high efficiency solar cell according to one embodiment of the present invention;

FIGS. 5A and 5B are cross-sectional views showing a manufacturing method of a two-terminal high efficiency solar cell using a layer transfer process (LTP) method and the two-terminal high efficiency solar cell manufactured by the method according to one embodiment of the present invention, respectively;

FIGS. 6A and 6B are cross-sectional views showing a manufacturing method of a four-terminal high efficiency solar cell using a layer transfer process (LTP) method and the four-terminal high efficiency solar cell manufactured by the method according to another embodiment of the present invention, respectively;

FIGS. 7A and 7B are cross-sectional views showing a manufacturing method using, as a HIT type solar cell substrate, a thick film similar to a single crystal manufactured by a layer transfer process method and using state thereof according to another embodiment of the present invention, respectively;

FIGS. 8A and 8B show the current-voltage characteristics of an existing crystal silicon tandem type solar cell using an amorphous silicon as a graph and a table, respectively; and

FIGS. 9A and 9B show the current-voltage characteristics of the solar cell in FIG. 6B according to one embodiment of the present invention as a graph and a table, respectively.

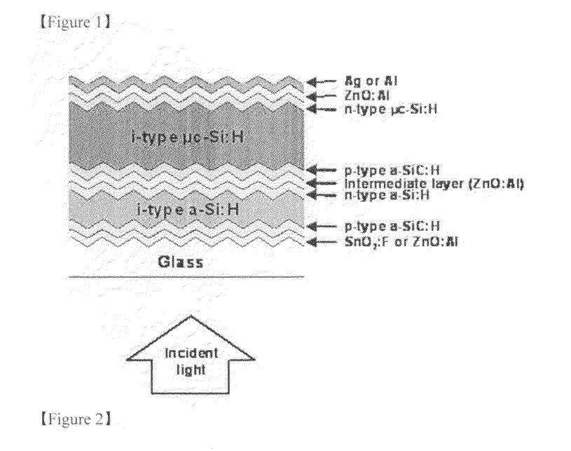

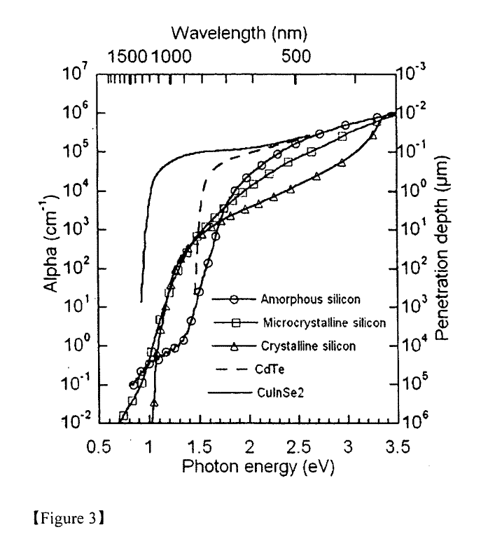

### BEST MODE

Hereinafter, the preferred embodiments of the present invention will be described with reference to the accompanying drawings. In referring reference numerals to the following drawings, the same reference numerals refer to the same components throughout the drawings. The detailed description of known functions and configurations will be omitted so as not to obscure the subject of the present invention with unnecessary detail.

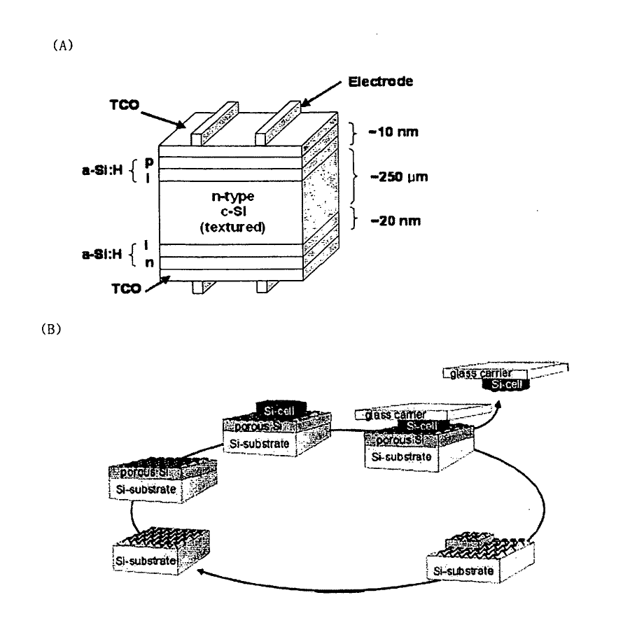

FIG. 3B shows a layer transfer process (LTP) using porous silicon.

Referring to FIG. 3B, a porous silicon thin film is formed on a textured silicon wafer and a thick film similar to a single crystal is then grown on the porous silicon thin film by using a chemical vapor deposition (CVD) method or a liquid phase epitaxy (LPE) method. This is used as a substrate like an existing wafer to manufacture a solar cell. Thereafter, this is bonded to glass, etc., and then separated therefrom using the weak coupling of the wafer used as the beginning substrate and the porous silicon thin film so that the solar cell is completed. This can lower raw material costs by recycling the wafer. Also, the characteristics of the thick film similar to the single crystal are much better than those of the thin film and the efficiency thereof is very high. It has been reported that the efficiency is more than 15%.

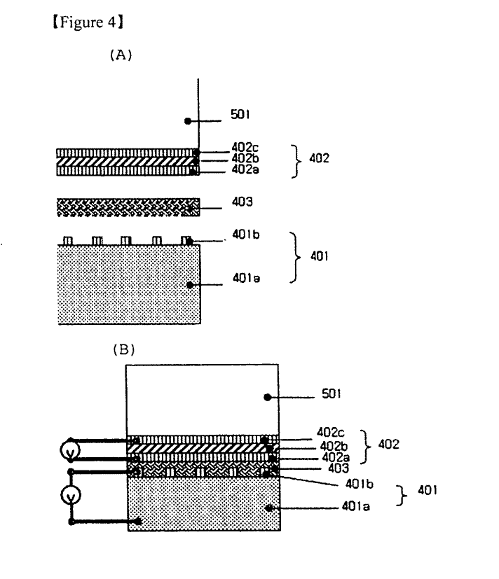

FIGS. 4A and 4B are cross-sectional views of a high efficiency solar cell according to one embodiment of the present invention;

In the embodiment, the solar cell comprises a lower solar cell layer 401, an upper solar cell layer 402, an intermediate layer 403, and a glass substrate 501.

The embodiment schematically indicates a method of stacking an amorphous silicon thin film directly on a silicon single crystal.

Referring to FIG. 4A, a metal emitter electrode 401b is formed on the upper portion of a single crystalline silicon-based pn thin film 401a to manufacture the lower solar cell layer. An upper electrode 402c, an amorphous silicon-based pin thin film 402b, and a lower electrode 401a are sequentially stacked on the upper portion of the glass substrate 501 to manufacture the upper solar cell layer 402. Thereafter, the upper solar cell layer 402 is turned over to be bonded to the lower solar cell layer 401. The intermediate layer 403 is formed between the upper solar cell layer 402 and the lower solar cell layer 401, wherein the intermediate layer 403 is preferably formed of transparent adhesive.

The solar cell formed as above becomes a four-terminal solar cell of the upper solar cell layer and the lower solar cell layer, as shown in FIG. 4B.

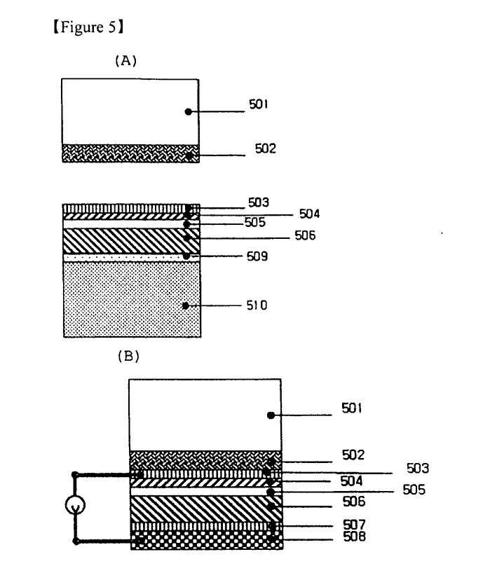

FIGS. 5A and 5B are cross-sectional views showing a manufacturing method of a two-terminal high efficiency solar cell using a layer transfer process (LTP) method and the two-terminal high efficiency solar cell manufactured by the method according to one embodiment of the present invention, respectively.

In this embodiment, the high efficiency solar cell using the layer transfer process (LTP) method comprises a glass substrate 501, a transparent adhesive 502, an upper electrode 503, an amorphous silicon-based pin thin film 504, an intermediate layer 505, a silicon-based pn epitaxial thin film 506, a backside reflection thin film 507, and a backside electrode 508. The embodiment schematically indicates a method of manufacturing a lower solar cell layer by the layer transfer process method and then stacking the amorphous silicon on the upper portion thereof.

Referring to FIG. 5A, a porous silicon thin film 509 is stacked on the upper portion of a crystal silicon 510 positioned at the lower portion of the solar cell and the silicon-based pn epitaxial thin film 506 is grown on the upper portion of the porous thin film 509. The intermediate layer 505 is formed on the upper portion of the silicon-based pn epitaxial thin film 506 and the silicon-based pin thin film 504 is formed on the upper portion of the intermediate layer 505. An upper electrode 503 is formed on the upper portion of the silicon-based pin thin film 504. The silicon-based pin thin film 504 is preferably formed of amorphous silicon. The upper electrode 503 is preferably formed of a transparent electrode to easily transmit light.

The silicon-based pn epitaxial thin film has the similar structure to the silicon single crystal shown in FIG. 4A. The structure of the solar cell shown in FIG. 5A may have the similar structure to the solar cell shown in FIG. 4A.

The glass substrate 501 is provided separately. The glass substrate 501 is stacked on the upper portion of the upper electrode 503, and the glass substrate 501 and the upper electrode 503 are preferably bonded by means of the transparent adhesive to easily transmit light.

In other words, the place receiving sunlight is formed with the amorphous silicon-based semiconductor 504 and the lower portion thereof is formed with the solar cell layer 506 manufactured by using the layer transfer process method. The amorphous silicon-based semiconductor is preferably formed of at least one layer. The solar cell layer formed of the amorphous silicon-based semiconductor and the solar cell layer formed using the layer transfer process method are electrically connected by interposing a transparent electrode or a tunnel recombination junction therebetween.

The amorphous silicon-based thin film 504 is preferably formed by means of the chemical vapor deposition (CVD) method. The solar cell layer 506 formed using the layer transfer process method is preferably manufactured as a substrate by growing the thin film similar to the single crystal on the silicon wafer using the chemical vapor deposition (CVD) method or the liquid phase epitaxy (LPE) method and then separating the thin film from the silicon wafer. While the present embodiment uses the method of forming the amorphous silicon-based pin thin film 504 on the upper portion of the pn epitaxial thin film 506 formed by the layer transfer process method, a method of forming the amorphous silicon-based pin thin film on the glass substrate 501 and then bonding it thereto can also be used.

Referring to FIG. 5B, after the bonding, the crystal silicon wafer 510 and the porous silicon 509 formed on the upper portion thereof are removed, and the backside reflection thin film 507 and the backside electrode 508 are sequentially formed on the lower portion of the silicon-based epitaxial pn thin film 506. The backside electrode 508 is formed of silver (Ag), aluminum (Al), TCO/Ag, TCO/Al, and so on.

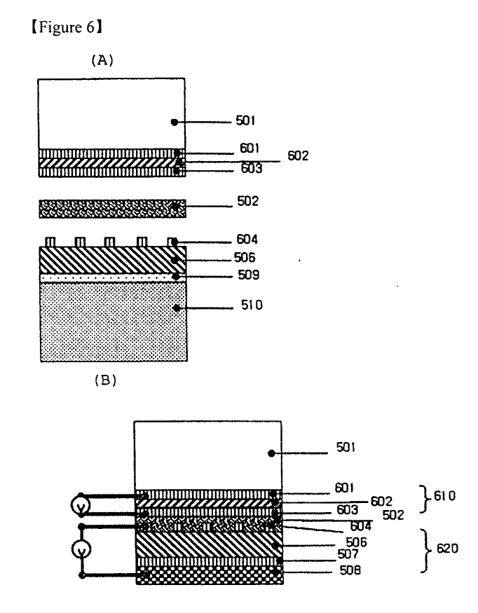

FIGS. 6A and 6B are cross-sectional views showing a manufacturing method of a four-terminal high efficiency solar cell using a layer transfer process (LTP) method and the four-terminal high efficiency solar cell manufactured by the method according to another embodiment of the present invention, respectively.

In the embodiment, the four-terminal high efficiency solar cell comprises a glass substrate 501, an upper solar cell layer 610, and a lower solar cell layer 620.

The embodiment schematically indicates a structure wherein the upper solar cell layer 610 and the lower solar cell layer 620 are formed independently.

Referring to FIG. 6A, the upper solar cell layer 610 comprises a first electrode 601, a silicon-based pin thin film 602, and a second electrode 603. The upper solar cell layer 610 is formed on the upper portion of the glass substrate 501. In other words, the first electrode 601, the silicon-based pin thin film 602 and the second electrode 603 are sequentially formed on the upper portion of the glass substrate 501. The silicon-based pin thin film 602 preferably uses amorphous silicon.

At the same time, the silicon thin film is formed by the layer transfer process method. In other words, the porous silicon 509 is stacked on the crystal silicon wafer 510 and the silicon-based pn epitaxial thin film 506 is grown on the upper portion of the porous silicon. A metal emitter electrode 604 is formed on the upper portion of the silicon-based pn epitaxial thin film 506. The silicon-based pn epitaxial thin film also has the similar structure to the silicon single crystal shown in FIG. 4A. The structure of the solar cell shown in FIG. 6A has approximately the same structure as the solar cell shown in FIG. 4A.

When the amorphous silicon-based pn thin film 602 is formed on the upper portion of the glass substrate 501 and the silicon-based pn epitaxial thin film 506 is grown on the upper portion of the crystal silicon wafer 510, both thin films are bonded by means of the transparent adhesive 502. Both thin films are preferably bonded to allow the second electrode 603 and the metal emitter electrode 604 to be adjacent to each other by turning over the glass substrate 501. As the adhesive 502, the transparent adhesive is preferably used in order to easily transmit light.

After bonding both thin films as above, the porous silicon 509 and the crystal silicon wafer 510 on which the silicon-based pn epitaxial thin film 506 is grown are removed and then, the backside reflection thin film 507 and the backside electrode 508 are sequentially formed on the lower portion of the silicon-based pn epitaxial thin film 506.

Thereafter, the first electrode 601 and the second electrode 603 are connected to form the upper solar cell layer 610 and the metal emitter electrode 604 and the backside electrode 508 are connected to form the lower solar cell layer 520.

Such a solar cell has a structure that the place receiving sunlight is formed with a single-layer or a multi-layer solar cell layer and the lower portion thereof is formed with the solar cell layer manufactured by using the layer transfer process method. The transparent adhesive serves as an insulating film to allow both cell layers to have an electrically insulated structure. The backside electrode is formed of silver (Ag), aluminum (Al), TCO/Ag, TCO/Al, and so on. Although not shown in the present invention, the present embodiment may use a method of growing both of the silicon-based pin epitaxial thin film and the amorphous silicon-based pn thin film on the crystal silicon wafer and then bonding only the glass substrate thereto.

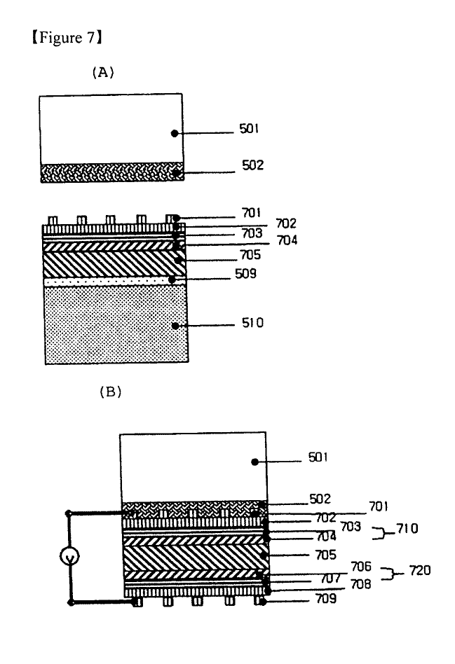

FIGS. 7A and 7B show a manufacturing method using, as an HIT type solar cell substrate, a thick film similar to a single crystal manufactured by a layer transfer process method and using state thereof according to one embodiment of the present invention, respectively. In the embodiment, the HIT type solar cell comprises a glass substrate 501, an upper metal emitter electrode 701, an upper electrode 702, a second amorphous silicon-based thin film 710, a silicon-based n-type epitaxial thin film 705, a first amorphous silicon-based thin film 720, a lower electrode 708, and a lower metal emitter electrode 709.

The embodiment schematically indicates a manufacturing method of the HIT type solar cell using the layer transfer process method.

Referring to FIG. 7A, forming the porous silicon 509 on the upper portion of the crystal silicon wafer 510 and using the layer transfer process method is the same as the foregoing description. The silicon-based n-type epitaxial thin film 705 is grown on the upper portion of the porous silicon 509, the silicon-based i-type thin film 704 and the silicon-based p-type thin film 703 are sequentially formed thereon and the upper metal 702 and the upper metal emitter electrode 701 are formed thereon.

Thereafter, the porous silicon 509 and the crystal silicon wafer 510 are removed as in the existing layer transfer process method and the silicon-based i-type thin film 706 and a silicon-based p-type thin film 707 are then formed on the lower portion of the silicon-based n-type epitaxial thin film 705. Then, the lower electrode 708 and the lower metal emitter electrode 709 are sequentially formed on the silicon-based p-type thin film 707. Next, the upper metal emitter electrode 701 and the lower metal emitter electrode 709 are connected and the glass substrate 501 is bonded to the upper metal emitter electrode 701 by means of the predetermined transparent adhesive 502 so that the solar cell is completed.

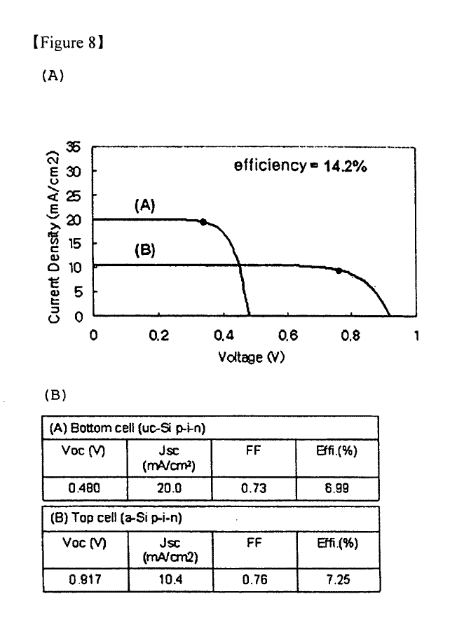

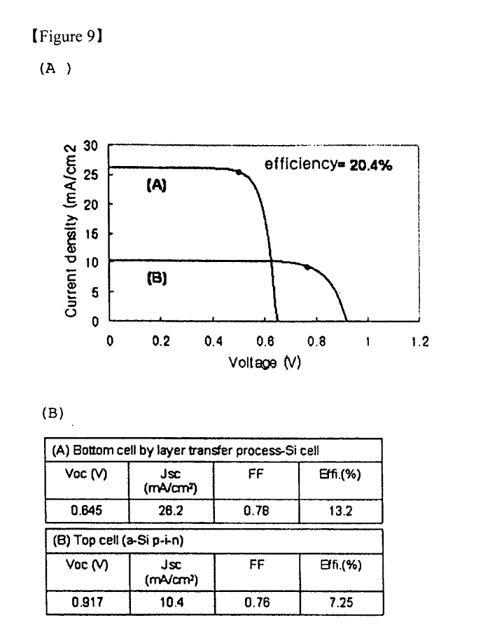

FIGS. 8A and 8B show the current-voltage characteristics of an existing crystal silicon tandem type solar cell using an amorphous silicon as a graph and a table, respectively and FIGS. 9A and 9B show the current-voltage characteristics of the solar cell in FIG. 6B according to one embodiment of the present invention as a graph and a table, respectively.

In the existing thin film a-Si/?-Si tandem four-terminal solar cell, the expectable maximum light conversion efficiency is 14.2% through the efficiency of each single junction solar cell that has been reported until now. In contrast, when using LTP-silicon as a bottom cell instead of the ?-Si, the light conversion efficiency expected in the four-terminal solar cell is about 20.4%.

It is assumed that the efficiency of the upper cell manufactured with the a-Si is 7.25% and the efficiency of the lower cell manufactured with the LTP-silicon is 13.2%. In the case of the a-Si, if the cell is manufactured independently and the backside reflector is used, it can be expected that the efficiency is about 12% or more, however, in the case of manufacturing the upper cell using the double junction, it has been reported that the efficiency is about 7.25%. Also, in the case of the lower cell using the LTP-silicon, if the cell is manufactured independently, it has been reported that the efficiency is now 16.6%, however, since the a-Si cell positioned at the upper portion attenuates the incident light, it can be expected that the potential efficiency is about 80%. As can be appreciated from the above calculation result, it can be expected that the solar cell according to the present invention becomes more efficient than the solar cell according to the existing tandem method.

Also, when the solar cell having the same structure as FIG. 7 but using the LTP-silicon is manufactured, it can be expected that the efficiency is high and the material cost is reduced by replacing the wafer with the thick film.

While the invention has been shown and described with reference to the preferred embodiments, it will be understood by those skilled in the art that various changes in form and details may be made therein without departing from the spirit and scope of the invention as defined by the appended claims.

### INDUSTRIAL APPLICABILITY

The present invention can be applied to a solar cell and a manufacturing method thereof using an advantage of a thin film solar cell and a layer transfer process (LTP) method, which has been developed through a silicon-on-insulator (SOI) method and which there have been attempts to apply to a solar cell in order to solve the problems that the efficiency of a low-cost thin film solar cell is low and that a high efficiency HIT solar cell is expensive.

1. A high efficiency solar cell comprising:
a lower solar cell layer comprising a silicon-based epitaxial thin film grown by a layer transfer process (LTP) method;
an upper solar cell layer stacked on the upper portion of the lower solar cell layer and comprising an amorphous silicon-based thin film; and
an intermediate layer between the upper solar cell layer and the lower solar cell layer.

2. The high efficiency solar cell as claimed in claim 1, wherein the lower solar cell layer comprises a metal electrode on the upper portion of the silicon-based thin film.

3. The high efficiency solar cell as claimed in claim 1, wherein the upper solar cell layer comprises an electrode on the upper and lower portions of the amorphous silicon-based thin film.

4. (canceled)

5. The high efficiency solar cell as claimed in claim 1, wherein the intermediate layer is formed of transparent adhesive.

6. (canceled)

7. The high efficiency solar cell as claimed in claim 1, wherein the lower solar cell layer is sequentially stacked with a backside electrode, a backside reflection thin film, and a silicon-based epitaxial thin film grown by a layer transfer process method.

8. The high efficiency solar cell as claimed in claim 7, wherein the backside electrode is formed of silver (Ag) or aluminum (Al).

9. The high efficiency solar cell as claimed in claim 1, wherein the upper solar cell layer is sequentially stacked with a second electrode, an amorphous silicon-based thin film, and a first electrode.

10. The high efficiency solar cell as claimed in claim 1, wherein the lower solar cell layer is sequentially stacked with a backside electrode, a backside reflection thin film, a silicon-based epitaxial thin film grown by a layer transfer process method, and a metal emitter electrode.

11. The high efficiency solar cell as claimed in claim 10, wherein the backside electrode is formed of silver (Ag) or aluminum (Al).

12. The high efficiency solar cell as claimed in claim 1, wherein the upper solar cell layer and the lower solar cell layer are bonded by means of transparent adhesive.

13. A high efficiency solar cell comprising:
a silicon-based epitaxial thin film grown by a layer transfer process (LTP) method;
a first amorphous silicon-based thin film formed on the lower portion of the silicon-based epitaxial thin film;
a second amorphous silicon-based thin film formed on the upper portion of the silicon-based epitaxial thin film;
an upper electrode and an upper metal emitter electrode formed on the upper portion of the first amorphous silicon-based thin film; and
a lower electrode and a lower metal emitter electrode formed on the lower portion of the second amorphous silicon-based thin film.

14. The high efficiency solar cell as claimed in claim 13, wherein the first amorphous silicon-based thin film is sequentially stacked with a p-type silicon thin film and an i-type silicon thin film.

15. The high efficiency solar cell as claimed in claim 13, wherein the second amorphous silicon-based thin film is sequentially stacked with an i-type silicon thin film and a p-type silicon thin film.

16. A manufacturing method of a high efficiency solar cell comprising the steps of:
growing a silicon-based epitaxial thin film by a layer transfer process (LTP) method and sequentially forming an intermediate layer, an amorphous silicon-based thin film and an upper electrode on the upper portion of the silicon-based epitaxial thin film; and
sequentially forming a backside reflection thin film and a backside electrode on the lower portion of the silicon-based epitaxial thin film.

17. A manufacturing method of a high efficiency solar cell comprising the steps of:
growing a silicon-based epitaxial thin film by a layer transfer process (LTP) method;
sequentially forming an upper electrode and an amorphous silicon-based thin film; and
bonding the silicon-based epitaxial thin film and the amorphous silicon-based thin film using an intermediate layer as a medium and sequentially forming a backside reflection thin film and a backside electrode on the lower portion of the silicon-based epitaxial thin film.

18. The method as claimed in claim 16 or 17, wherein the amorphous silicon-based thin film is formed by a chemical vapor deposition (CVD) method.

19. A manufacturing method of a high efficiency solar cell comprising the steps of:
growing a silicon-based epitaxial thin film by a layer transfer process (LTP) method and sequentially fanning a metal emitter electrode, an insulating layer, a second electrode, an amorphous silicon-based thin film, and a first electrode on the upper portion of the silicon-based epitaxial thin film;
sequentially forming an intermediate layer, an amorphous silicon-based thin film, and an upper electrode; and
sequentially forming a backside reflection thin film and a backside electrode on the lower portion of the silicon-based epitaxial thin film.

20. A manufacturing method of a high efficiency solar cell comprising the steps of:
growing a silicon-based epitaxial thin film by a layer transfer process (LTP) method and then forming a metal emitter electrode on the upper portion of the silicon-based epitaxial thin film;
sequentially forming a first electrode, an amorphous silicon-based thin film and a second electrode; and
bonding the second electrode and the metal emitter electrode and sequentially forming a backside reflection thin film and a backside electrode on the lower portion of the silicon-based epitaxial thin film.

21. A manufacturing method of a high efficiency solar cell comprising the steps of:
growing a silicon-based n-type epitaxial thin film by a layer transfer process (LTP) method and sequentially stacking an i-type amorphous silicon-based thin film, a p-type amorphous silicon-based thin film, an upper electrode and an upper metal emitter electrode on the upper portion of the silicon-based n-type epitaxial thin film; and
sequentially stacking an i-type amorphous silicon-based thin film, a p-type amorphous silicon-based thin film, a lower electrode and a lower metal emitter electrode on the lower portion of the silicon-based epitaxial thin film.

22. A manufacturing method of a high efficiency solar cell comprising the steps of:
forming a metal emitter electrode on the upper portion of a single crystalline silicon-based thin film to form a lower solar cell layer;
sequentially forming an upper electrode, an amorphous silicon-based thin film and a lower electrode to form an upper solar cell layer; and
bonding the lower solar cell layer and the upper solar cell layer.
